(19) United States
(12) Patent Application Publication
(10) Pub. No.: US 2009/0184719 A1
(43) Pub. Date: Jul. 23, 2009

(54) IC TESTING ENVIRONMENT INVESTIGATIVE DEVICE AND METHOD

(76) Inventors: Hsuan-Chung Ko, Hsin-Chu (TW); Chen-Yang Hsieh, Hsin-Chu (TW)

Correspondence Address: STOUT, UXA, BUYAN & MULLINS LLP, 4 VENTURE, SUITE 300, IRVINE, CA, 92618, US

(21) Appl. No.: 12/135,983

(22) Filed: Jun. 9, 2008

(30) Foreign Application Priority Data
Jan. 18, 2008 (TW) 097102027

(51) Int. Cl. G01R 29/08; G01R 31/00; H01Q 9/04

(52) U.S. Cl. 324/537; 343/703; 343/700 MS

(57) ABSTRACT

A device and method for investigating the IC (integrated circuit) testing environment is disclosed herein. The investigative device comprises a loadboard, a socket and an antenna. The loadboard is disposed in the bottom of the investigative device. The socket is disposed over the loadboard. The socket is used to fasten the element under test (such as IC) and the element under test is electrically connected to the loadboard. The antenna is also disposed in a position over the loadboard and closed to the socket. The purpose to dispose the antenna is to receive the wireless signal and monitor the testing environment if there is too much noise around the testing environment to jam the IC testing.

### BACKGROUND OF THE INVENTION

1. Field of the Invention

The present invention generally relates to an investigative device, and more particularly to an investigative device for integrated circuit testing environment.

2. Description of the Prior Art

While testing the element of the radio frequency circuit, the detection of manufacturing environment is required to execute. Because manufacturing environment may be affected by the radio frequency noise and the testing might fail, Pass-bin becomes Fail-bin or Fail-bin becomes Pass-bin. Therefore, before production, the using of radio communication devices or others are usually restricted that could affect the testing of high frequency elements. But general detection of manufacturing environment only performs limited protection, such as the indoor noise from the reflection or scattering of Auto Test Equipment (ATE). General detection of manufacturing environment is not effective to detect radio frequency noise around the element under test, and it is difficult to determine if the radio frequency noise is excess to make the pin testing fail. In other words, the detection method of the manufacturing environment described above could reduce the jamming of radio frequency noise, but cannot detect the influence by the noise around the manufacturing environment.

For the reason above, it is necessary to provide an investigative device and method for detecting the noise of manufacture environment by simulating a testing environment.

### SUMMARY OF THE INVENTION

In view of the foregoing, the object of the present invention is to provide an investigative device for integrated circuits (IC) to detect whether noise is excess around the testing environment of IC.

The other object of the present invention is to provide an investigative method for integrated circuits to detect whether noise is excess around the testing environment to affect the testing result of IC.

According to the foregoing objects, the present invention provides an investigative device for the testing environment of IC. This investigative device includes a loadboard, a socket and an antenna at least. The loadboard is located in the bottom of the investigative device, and the socket is located on the loadboard to fasten an element (ex. IC) under test, thus the element under test is electrically connected to the loadboard. The antenna is used to receive the wireless signals, and is located near the socket on the loadboard.

According to the other objects, the present invention provides an investigative method for the testing environment of IC. This investigative method includes the following steps at least: placing the antenna on the loadboard, receiving the wireless signals by the antenna, and analyzing the wireless signals from the antenna by the test program or the frequency spectrum analyzer.

### BRIEF DESCRIPTION OF THE DRAWINGS

FIG. 1 shows an investigative device for the testing environment of IC according to an embodiment of the present invention.

FIG. 2A through 2C are graphs illustrating the antenna of the investigative device according to the present invention.

FIG. 3 illustrates the testing environment according to the present invention.

FIG. 4 shows a flow chart of the investigative method according to an embodiment of the present invention.

### DETAILED DESCRIPTION OF THE INVENTION

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

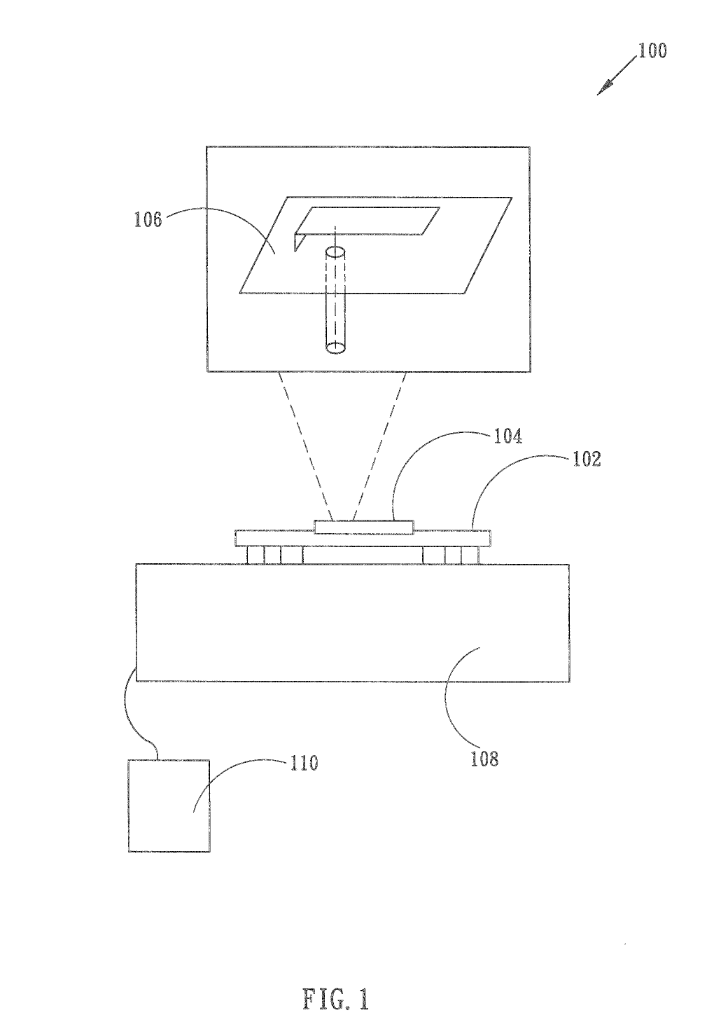

FIG. 1 shows an investigative device for the testing environment of IC (integrated circuit) according to an embodiment of the present invention. As shown in FIG. 1, the investigative device 100 includes loadboard 102, socket 104 and antenna 106. The loadboard 102 is located in the bottom of the investigative device 100. The investigative device 100 is electrically connected to the surrounding instruments (ex. computer and monitor) through the loadboard 102. There are one socket 104 installed on the loadboard 102, and each socket 104 is used to fasten the element under test, so that the element is electrically connected to the loadboard 102. The antenna 106 is located on the loadboard 102, and the ground of the antenna 106 is also electrically connected to the ground of the loadboard 102. The antenna 106 could be placed on anywhere on the loadboard 102. In the preferred embodiment, the antenna 106 is placed near the socket 104. The antenna 106 receives the wireless signals around the testing environment to monitor whether the wireless signals are excess to jam the IC. In the other embodiment, the investigative device 100 comprises a tester head 108 to load the loadboard 102. The investigative device 100 is preferred to simulate the testing environment of the radio frequency IC, and also suited to other IC being jammed by different signals. The investigative device 100 is mounted on an automatic machine, and transmitted to different places by automatic machine for testing.

Still refer to FIG. 1. The investigative device 100 includes a frequency spectrum analyzer 110 which is electrically connected to the loadboard 102. The wireless signals received by the antenna 106 are transmitted to the loadboard 102, and then analyzed by frequency spectrum analyzer 110. The frequency spectrum analyzer 110 is able to analyze the intensity and the character of the wireless signals, and monitor the noise which may jam the IC testing.

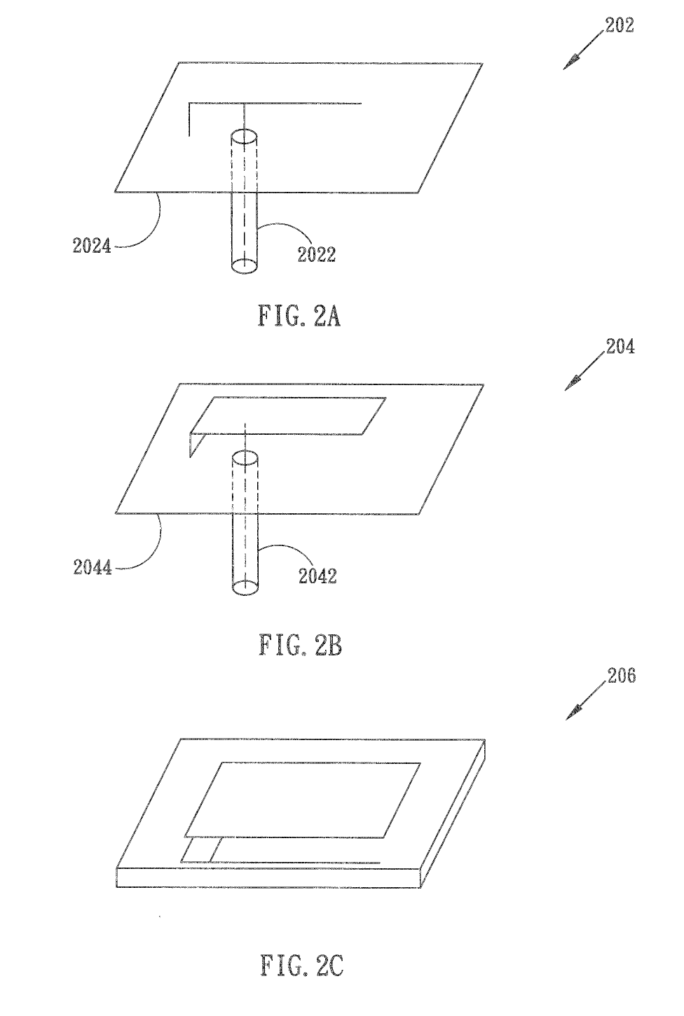

FIG. 2A through 2C illustrate the antenna of the investigative device. As shown in FIG. 2A, the antenna is a conventional wire element inverted F antenna 202. The conventional wire element inverted F antenna 202 includes a signal transmission terminal 2022 and a ground 2024. The signal transmission terminal 2022 transmits the wireless signal received by the antenna to the surrounding instruments (ex. computer or frequency spectrum analyzer) for advanced analysis, and the ground 2024 is electrically connected to the ground of the loadboard 102 (not shown) of the investigative device. As shown in FIG. 2B, the antenna is a planar inverted F antenna 204. The planar inverted F antenna 204 also includes a signal transmission terminal 2042 and a ground 2044. The signal transmission terminal 2042 transmits the wireless signal received by the antenna to the surrounding instruments (ex. computer or frequency spectrum analyzer) for advanced analysis, and the ground 2044 is electrically connected to the ground of the loadboard 102 (not shown) of the investigative device. Comparing with the conventional wire element inverted F antenna 202 in FIG. 2A, the planar inverted F antenna 204 is capable of better receiving character and not affected by the copper plate or the ground circuit below. Therefore, the planar inverted F antenna 204 is suitable to be the receiving antenna combined with the loadboard 102 in the present invention.

But in the different embodiments, the integrated inverted F antenna 206 shown in FIG. 2C or other antennas (ex. Film antenna, planar antenna, multi-arm monopole antenna and the combination thereof) which are able to receive multi-band frequency signals are also used to be the antenna in the present invention. The foregoing antennas are also capable of detecting wireless signals, and the receiving performance of the planar inverted F antenna 204 is better. The antenna pattern of the planar inverted F antenna 204 is better and not affected by the ground easily.

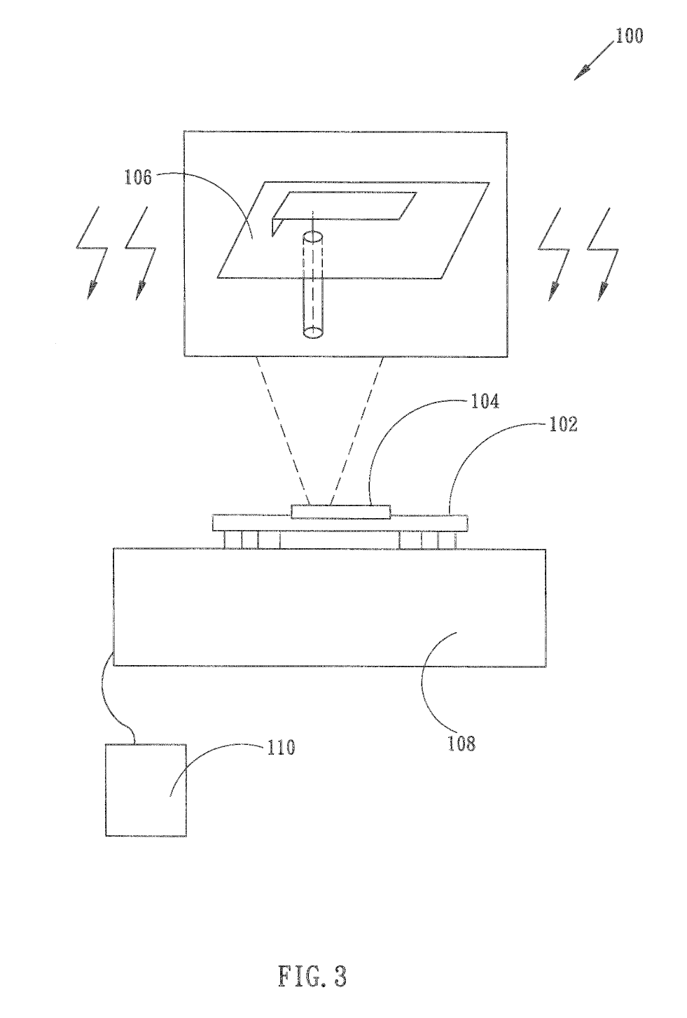

FIG. 3 illustrates the testing environment according to the present invention. As shown in FIG. 3, before the element under test (not shown) is placed on the socket 104 of the investigative device 100, the antenna 106 scans the wireless signals around the investigative device 100 to monitor whether the wireless signals are excess to jam the accuracy of the element testing. For example, Pass-bin becomes Fail-bin or Fail-bin becomes Pass-bin. If the scanning result shows that the wireless signals are not excess, the element under test would be placed on the socket 104 for being tested. Meanwhile, the antenna 106 continues to scan the wireless signals around the investigative device 100, because any wireless transmitting/receiving, such as mobile phone, laptop computer or personal digital assistant (PDA), will jam the element testing. Moreover, the element under test on the investigative device 100 would be moved as the automatic machine moves, the testing environment of the element under test will vary. The antenna 106 scans the wireless signals of different testing environment and transmits the wireless signals to the frequency spectrum analyzer 110 for analyzing. The analysis result would be transmitted to a terminating machine (ex. computer). The terminating machine includes a testing program which decides to continue the element testing or stop the element testing to remove the wireless signal source according to the analysis result.

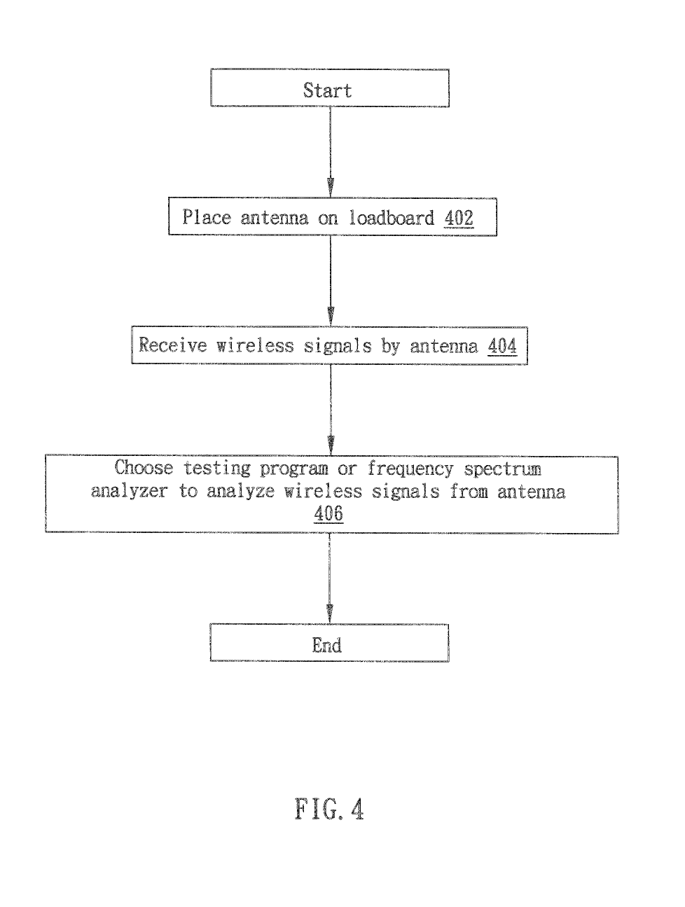

FIG. 4 shows a flow chart of the investigative method according to an embodiment of the present invention. As shown in FIG. 4, the antenna is placed on the loadboard to scan the wireless signals around the testing environment in step 402. In step 404, the wireless signals are received by the antenna. In step 406, the testing program or the frequency spectrum analyzer could be chosen to analyze the wireless signals from the antenna. The antenna described above is used to scan the noise from the wireless network or the wireless mobile phone around the testing environment, and the ground of the antenna is electrically connected to the ground of the loadboard. The antenna is placed near the socket which is used to fasten the IC under test. The frequency spectrum analyzer is for analyzing the wireless signals from the antenna. The film antenna, the planar antenna or the combination thereof could be chosen in this investigative method described above. The antenna herein could be also the inverted F antenna (ex. planar inverted F antenna). This investigative method is preferred for the testing of the radio frequency IC.

Although specific embodiments have been illustrated and described, it will be appreciated by those skilled in the art that various modifications may be made without departing from the scope of the present invention, which is intended to be limited solely by the appended claims.

What is claimed is:

1. An investigative device for testing environment of circuits, comprising:
a loadboard;
a socket placed on said loadboard, and used to fasten an element under test so that said element under test is electrically connected to said loadboard; and
an antenna placed on said loadboard near said socket, and used for receiving a wireless signal.

2. The investigative device according to claim 1, wherein the ground of said antenna is electrically connected to the ground of said loadboard.

3. The investigative device according to claim 1, further comprising a frequency spectrum analyzer for analyzing the wireless signal transmitted from said antenna.

4. The investigative device according to claim 1, wherein said antenna is selected from the group consisting of a film antenna, a planar antenna or the combination thereof.

5. The investigative device according to claim 1, wherein said antenna is an inverted F antenna.

6. The investigative device according to claim 5, wherein said inverted F antenna is a planar inverted F antenna.

7. The investigative device according to claim 1, further comprising a testing program to analyze the wireless signal transmitted from said antenna.

8. The investigative device according to claim 1, wherein said element under test is a radio frequency integrated circuit.

9. A investigative method for testing environment of circuits, comprising:
placing an antenna on a loadboard;
receiving a wireless signal by said antenna; and
choosing one from a testing program and a frequency spectrum analyzer to analyze the wireless signal transmitted from said antenna.

10. The investigative method according to claim 9, wherein the ground of said antenna is electrically connected to the ground of said loadboard.

11. The investigative method according to claim 9, wherein said frequency spectrum analyzer is used to analyze the wireless signal transmitted from said antenna.

12. The investigative method according to claim 9, wherein said antenna is selected from the group consisting of a film antenna, a planar antenna or the combination thereof.

13. The investigative method according to claim 9, wherein said antenna is an inverted F antenna.

14. The investigative method according to claim 9, wherein said antenna is a planar inverted F antenna.

15. The investigative method according to claim 9, wherein said investigative method is for the testing of an integrated circuit.

16. The investigative method according to claim 9, wherein said antenna is used to scan the noise from the wireless network or the wireless mobile phone around the testing environment.

17. The investigative method according to claim 9, wherein said antenna is placed near a socket, and said socket is used to fasten said integrated circuit under test.

18. An investigative device for testing environment of integrated circuits, comprising:
a tester head;
a loadboard placed on and electrically connected to said tester head;
a socket placed on said loadboard, and used to fasten an element under test so that said element under test is electrically connected to said loadboard; and
an antenna placed on said loadboard near said socket, and used for receiving a wireless signal;
wherein said investigative device is used in a detecting machine.

19. The investigative device according to claim 18, wherein the ground of said antenna is electrically connected to the ground of said loadboard.

20. The investigative device according to claim 18, further comprising a frequency spectrum analyzer for analyzing the wireless signal transmitted from said antenna.

21. The investigative device according to claim 18, wherein said antenna is selected from the group consisting of a film antenna, a planar antenna or the combination thereof.

22. The investigative device according to claim 18, wherein said antenna is an inverted F antenna.

23. The investigative device according to claim 22, wherein said antenna is a planar inverted F antenna.

24. The investigative device according to claim 18, further comprising a testing program to analyze the wireless signal transmitted from said antenna.

25. The investigative device according to claim 18, wherein said element under test is a radio frequency integrated circuit.
